(19) United States
(12) Patent Application Publication
(10) Pub. No.: US 2012/0118235 A1
(43) Pub. Date: May 17, 2012

(54) FILM COATING DEVICE

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/981,566

(22) Filed: Dec. 30, 2010

(30) Foreign Application Priority Data
Nov. 17, 2010 (TW) 99139615

(51) Int. Cl. C23C 16/458; C23C 16/455

(52) U.S. Cl. 118/728

(57) ABSTRACT

A film coating device includes a film coating holder, a film coating cover, and a filter plate. The film coating holder includes a number of through holes defined therein for receiving workpieces to be coated. The film coating cover covers the film coating holder from a top side of the film coating holder. The filter plate is mounted on a bottom of the film coating holder, and defines a number of filter holes for letting vaporized coating material through and blocking impurities.

### BACKGROUND

1. Technical Field

The present disclosure relates to film coating devices, particularly to a film coating device with a film coating holder.

2. Description of Related Art

In a film coating process for workpieces (e.g., lenses), the workpieces are generally placed on a film coating holder. In a single-side film coating process, when a surface of each workpiece is being coated, an opposite surface of each workpiece may be contaminated by the coating material. Moreover, the surface being coated may be polluted by impurity.

Thus, what is needed is a new film coating device to overcome the shortcomings described above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic, isometric view of a film coating device in accordance with an embodiment.

FIG. 2 is a schematic, exploded view of the film coating device of FIG. 1.

### DETAILED DESCRIPTION

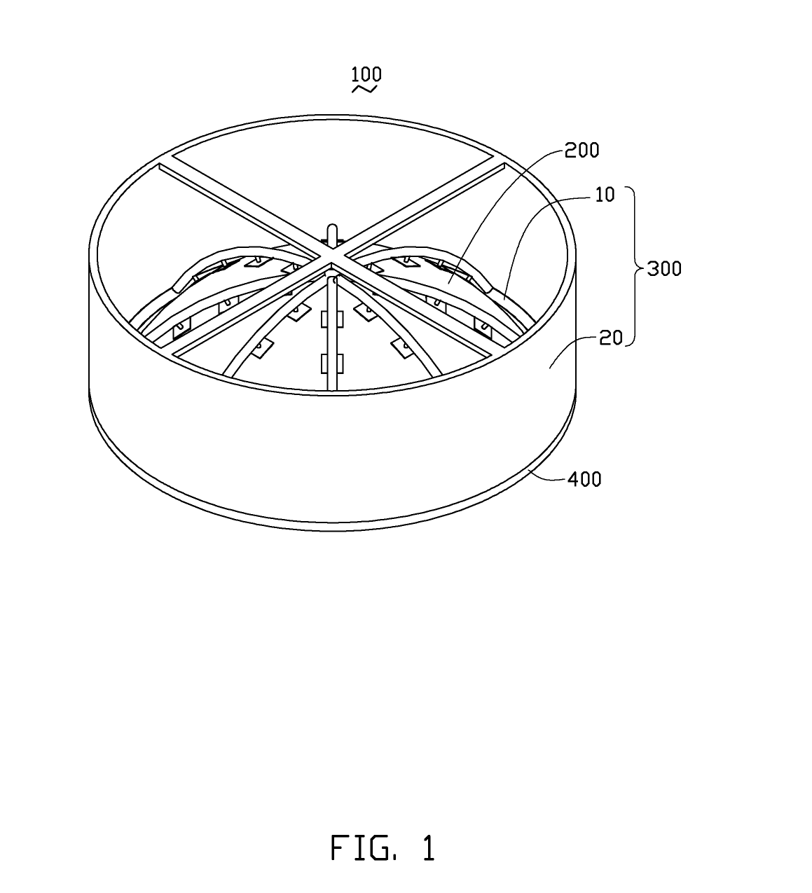

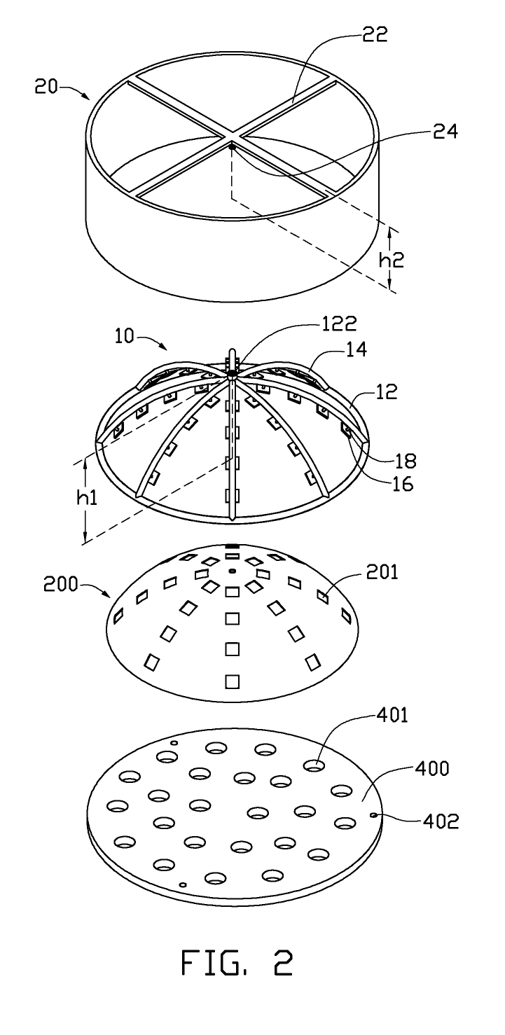

Referring to FIGS. 1 and 2, a film coating device 100, in accordance with an embodiment, includes a film coating holder 200, a film coating cover 300, and a filter plate 400.

The film coating holder 200 includes a plurality of through holes 201 defined therein for receiving the workpieces (not shown) to be coated. Each through hole 201 has the same size as each other and is arranged in a predetermined order. The film coating holder 200 is substantially umbrella-shaped. In coating process, the coating material is placed under the film coating holder 200. The film coating holder 200 is made of a highly thermally conductive metallic material, such as copper, aluminum, or stainless steel.

The film coating cover 300 includes a first cover body 10 and a second cover body 20. The first cover body 10 covers the film coating holder 200. The second cover body 20 covers the first cover body 10.

Referring to FIG. 2, the first cover body 10 is substantially umbrella-shaped and includes a circular frame 12 and eight arc-shaped arms 14. One end of each arc-shaped arm 14 is connected to the circular frame 12, and the other end of each arc-shaped arm 14 is connected to each other. Each arc-shaped arm 14 is equidistant to each other. A plurality of shelter pieces 16 is arranged on the inner side of each arc-shaped arm 14. Each shelter piece 16 is rotatably mounted on the arc-shaped arm 14 through a connecting shaft 18. Each connecting shaft 18 is rotatably connected to the arc-shaped arm 14, thus, each shelter piece 16 can rotate to a certain angle. In the present embodiment, each shelter piece 16 has the same size as each other and is symmetrically arranged on the first cover body 10. The shape of each shelter piece 16 is set as the same shape as the through holes 201 of the film coating holder 200, and the arrangement of the shelter pieces 16 is corresponding to that of the through holes 201 of the film coating holder 200.

In coating, the coating material vaporizes and the vapor of the coating material rises upward from the underside of the film coating holder 200. The surface of each workpiece, which is opposing the coating material, will be coated by the vapors of the material, and an opposite surface of each workpiece will remain clean without contamination. The first cover body 10 can cover the upward surface of each workpiece that is not required to be coated, to prevent the upper surface of each workpiece from being contaminated. On the other hand, each shelter piece 16 presses the corresponding workpiece to prevent it from warping and deforming.

The second cover body 20 covers the first cover body 10. If the height of the first cover body 10 is h1 and the height of second cover body 20 is h2, the height h2 of the second cover body 20 should be no less than the height h1 of the first cover body 10. Accordingly, the second cover body 20 can receive the first cover body 10 therein. The second cover body 20 is columnar or umbrella-shaped. In the present embodiment, the second cover body 20 is columnar and hollow, and has a cross-shaped beam 22 on the top. A bolt 24 opposing the holder 10 is arranged on the center of the beam 22. Accordingly, a screw hole 122 is defined in the top center of the first cover body 10. The first cover body 10 can be fixed to the second cover body 20 by engaging the bolt 24 into the screw hole 122. It is to be understood that the first and the second cover bodies 10, 20 can be fixed by other means, such as, by hinge or rope.

The first cover body 10, the second cover body 20 and the film coating holder 200 are all circular, and the diameters of the bottom surfaces of these three parts match with each other. In the present embodiment, the diameter of the bottom surface of the first cover body 10 is slightly larger than that of the film coating holder 200, and slightly less than that of the second cover body 20. Therefore, the film coating holder 200 can be covered by the first cover body 10, and the first cover body 10 and the film coating holder 200 can be entirely covered by the second cover body 20. So, the vapor of the material will not make direct contact with the periphery of the film coating holder 200 and the first cover body 10. By using the first and second cover bodies 10, 20, the film coating holder 200 and the workpieces can avoid contamination from the coating material to effectively film coat the desired area without contaminating surrounding areas.

The filter plate 400 is circular. The diameter of the filter plate 400 matches with the diameter of the bottom surface of the first cover body 10. The filter plate 400 defines a plurality of filter holes 401 and a plurality of fixing holes 402 thereon. Screws (not shown) pass through the fixing holes 402 and screw holes (not shown) defined on the first cover body 10, thus the filter plate 400 can mount on the bottom of the first cover body 10. It is to be understood that the first cover body 10 and the filter plate 400 can be fixed by other means, such as, by hinge or rope.

The coating material and the impurities have different physical characteristic, as a result, in coating, the coating material will be vaporized, and the impurities will not. Thus, the singular body of the impurities is bigger than that of the vaporized coating material. The filter holes 401 let the vaporized coating material through, and block the impurities. The diameter of each of the filter holes 401 may be different corresponding to different coating materials. In this embodiment, the diameter of each filtering holes is about 15 millimeters to about 20 millimeters.

The film coating holder 200 and the filter plate 400 are also made of a highly thermally conductive metallic material, such as copper, aluminum, or stainless steel.

In operation, first, the workpieces are received in the corresponding through holes 201. Second, the first cover body 10 is placed onto the film coating holder 200 to cover it, and each shelter piece 16 is aligned to a corresponding through hole 201. Third, the second cover body 20 is covered on the first cover body 10 and the film coating holder 200. Fourth, the first and the second cover bodies 10, 20 are fixed with each other by coupling the bolt 24 to the screw hole 122. Fifth, the filter plate 400 is mounted on the bottom of the first cover body 10 by screwing. The film coating device 100 is thus assembled and can be used to conduct the film coating process.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A film coating device, comprising:
a film coating holder, the film coating holder comprising a plurality of through holes defined therein for receiving workpieces to be coated;
a film coating cover configured for covering the film coating holder from a top side of the film coating holder; and
a filter plate mounted on a bottom of the film coating holder, and defining a plurality of filter holes configured for letting vaporized coating material through and blocking impurities.

2. The film coating device of claim 1, wherein the film coating cover comprises a first cover body and a second cover body, the first cover body comprises a frame, a plurality of arms, and a plurality of shelter pieces set on the inner sides of the arms correspondingly, each shelter piece is spatially arranged corresponding to a corresponding one of the through holes, the arms are positioned on the frame, the second cover body is configured for covering the first cover body, and the height of the second cover body is no less than that of the first cover body.

3. The film coating device of claim 2, wherein a shape of each of the shelter pieces is set as the same as that of each of the through holes.

4. The film coating device of claim 2, wherein the shelter pieces have the same size as each other and are symmetrically arranged on the first cover body, corresponding to the through holes that are symmetrically arranged.

5. The film coating device of claim 2, wherein each shelter piece is rotatably mounted on the inner side of the arm through a connecting shaft, and the connecting shaft is rotatably connected to the arm.

6. The film coating device of claim 2, wherein the diameters of the bottom surfaces of the first cover body, the second cover body and the film coating holder match with each other.

7. The film coating device of claim 2, wherein one end of each arm is connected to the periphery of the frame, and the other end of each arm is connected to each other.
